(19) United States
(12) Patent Application Publication
(10) Pub. No.: US 2024/0164121 A1
(43) Pub. Date: May 16, 2024

(54) TRANSPARENT PANEL AND DISPLAY DEVICE

(71) Applicant: NAN YA PLASTICS CORPORATION, TAIPEI (TW)

(72) Inventors: Te-Chao Liao, Taipei (TW); Chun-Che Tsao, TAIPEI (TW); Yi-Chen Chou, TAIPEI (TW)

(73) Assignee: NAN YA PLASTICS CORPORATION, TAIPEI (TW)

(21) Appl. No.: 18/153,361

(22) Filed: Jan. 12, 2023

(30) Foreign Application Priority Data
Nov. 11, 2022 (TW) 111143211

(51) Int. Cl. H10K 30/82; G06F 3/041; H10K 39/10

(52) U.S. Cl. CPC H10K 30/82; G06F 3/0412; H10K 39/10

(57) ABSTRACT

A transparent panel and a display device are provided. The transparent panel includes a substrate, a touch sensing module, and an organic photovoltaic module. The substrate has a first surface and a second surface opposite to the first surface. The touch sensing module is disposed on the first surface of the substrate. The organic photovoltaic module is disposed on the second surface of the substrate. An average visible transmittance of the transparent panel is greater than 70%.

### CROSS-REFERENCE TO RELATED APPLICATION

This application claims the priority benefit of Taiwan application serial no. 111143211, filed on Nov. 11, 2022. The entirety of the above-mentioned patent application is hereby incorporated by reference herein and made a part of this specification.

### BACKGROUND

### Technical Field

The disclosure relates to a panel and an optical device, and more particularly, to a transparent panel and a display device.

### Description of Related Art

With the advancement of technology, panels have been widely used in various display devices, such as mobile phones, wearable devices, computers, etc., and can have both touch and photoelectric conversion functions. Generally speaking, in order to make the panel have touch and solar charging functions, it is necessary to combine a substrate with a touch layer and another substrate with a photoelectric conversion function. The combination of the two substrates results in the thickness of a panel with this dual function being large, which is not conducive to today's trend of thin and miniaturized products.

### SUMMARY

The disclosure provides a transparent panel and a display device. The transparent panel has touch and photoelectric conversion functions as well as thin thickness and high transparency, which is adapted for application in a display device to improve the overall performance of the display device.

The transparent panel of the disclosure includes a substrate, a touch sensing module, and an organic photovoltaic module. The substrate has a first surface and a second surface opposite to the first surface. The touch sensing module is disposed on the first surface of the substrate. The organic photovoltaic module is disposed on the second surface of the substrate. An average visible transmittance of the transparent panel is greater than 70%.

In an embodiment of the disclosure, the above-mentioned organic photovoltaic module includes a first electrode, a hole transporting layer, an active layer, an electron transporting layer, an exciton blocking layer, and a second electrode. The first electrode is disposed on the second surface of the substrate. The hole transporting layer is disposed on the first electrode. The active layer is disposed on the hole transporting layer. The electron transporting layer is disposed on the active layer. The exciton blocking layer is disposed on the electron transporting layer. The second electrode is disposed on the exciton blocking layer.

In an embodiment of the disclosure, the above-mentioned active layer includes an acceptor material and a donor material.

In an embodiment of the disclosure, the above-mentioned donor material is selected from a group consisting of SubPc, CuPc, PBDTTT-C-T, NPB-DPA, ClA1Pc, and PtPc.

In an embodiment of the disclosure, the above-mentioned acceptor material is selected from a group consisting of carbon 60, carbon 70, PC60BM, PC61BM, PC70BM, and PC71BM.

In an embodiment of the disclosure, a material of the first electrode includes transparent conductive oxide, and a material of the second electrode includes metal, metal oxide or metal alloy.

The display device of the disclosure includes a transparent panel and a display. The transparent panel includes a substrate, a touch sensing module, and an organic photovoltaic module. The substrate has a first surface and a second surface opposite to the first surface. The touch sensing module is disposed on the first surface of the substrate. The organic photovoltaic module is disposed on the second surface of the substrate. An average visible transmittance of the transparent panel is greater than 70%. The display is disposed on a surface of the organic photovoltaic module away from the substrate.

In an embodiment of the disclosure, the above-mentioned display device includes a display area and a non-display area, and the organic photovoltaic module overlaps the display area in a normal direction of the substrate.

Based on the above, the transparent panel of the disclosure may integrate the touch sensing module and the organic photovoltaic module on the same substrate, and the transparent panel with touch and solar charging functions may be obtained without combining the two substrates. Thus, the overall thickness of the transparent panel may be reduced. In addition, the active layer of the organic photovoltaic module of the disclosure adopts organic materials and has high transmittance to visible light, and combined with high-penetration electrodes, the average visible transmittance of the transparent panel is greater than 70%, and the color rendering index is greater than 90%. Thus, the transparent panel is adapted for application in a display device to provide touch and photoelectric conversion functions for the display device.

### BRIEF DESCRIPTION OF THE DRAWINGS

FIG. 1 is a schematic cross-sectional view of a transparent panel according to an embodiment of the disclosure.

FIG. 2 is a schematic cross-sectional view of an organic photovoltaic module according to an embodiment of the disclosure.

FIG. 3 is a schematic cross-sectional view of a display device according to an embodiment of the disclosure.

### DESCRIPTION OF THE EMBODIMENTS

In the drawings, for clarity, the thickness of layers, films, plates, areas, and the like are magnified. Throughout the specification, the same reference numerals denote the same elements. It should be understood that when an element such as a layer, a film, an area, or a substrate is indicated to be “on” another element or “connected to” another element, it may be directly on another element or connected to another element, or an element in the middle may exist. In contrast, when an element is indicated to be “directly on another element” or “directly connected to” another element, an element in the middle does not exist. As used herein, “to connect” may indicate to physically and/or electrically connect. Furthermore, “electrically connected” or “coupled” may refer to the existence of other elements between two elements.

It should be understood that although the terms “first”, “second”, etc. may be used herein to describe various elements, parts, areas, layers and/or sections, these elements, parts, areas, and/or sections should not be limited by these terms. These terms are merely used to distinguish one element, part, area, layer or section from another element, part, area, layer or section. Thus, “a first element,” “part,” “area,” “layer” or “section” discussed below could be termed a second element, part, area, layer or section without departing from the teachings herein.

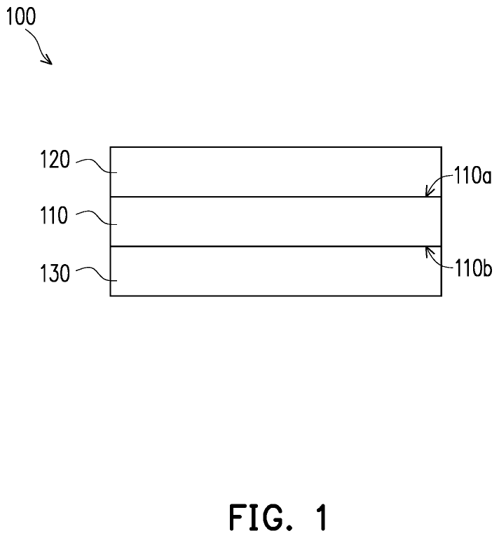

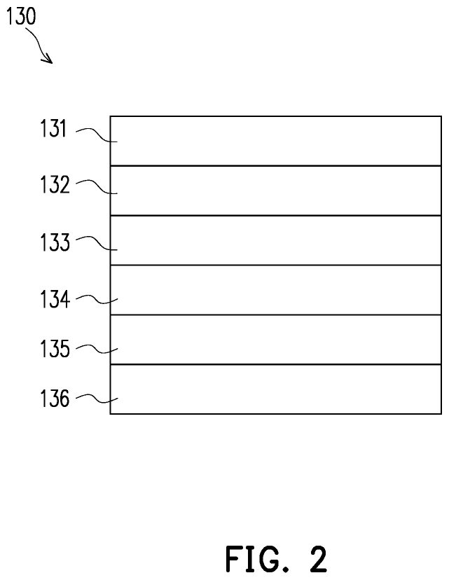

FIG. 1 is a schematic cross-sectional view of a transparent panel according to an embodiment of the disclosure. FIG. 2 is a schematic cross-sectional view of an organic photovoltaic module according to an embodiment of the disclosure. It should be noted that FIGS. 1 and 2 merely schematically illustrate the relative relationship between the positions of the various layers in the structure, and thicknesses of the various layers and the relative relationship between the thicknesses may be adjusted according to actual needs, which is not limited in the disclosure.

Referring to FIG. 1, a transparent panel 100 includes a substrate 110, a touch sensing module 120, and an organic photovoltaic module 130. The substrate 110 has a first surface 110a and a second surface 110b opposite to the first surface 110a. The touch sensing module 120 is disposed on the first surface 110a of the substrate 110. The organic photovoltaic module 130 is disposed on the second surface 110b of the substrate 110. An average visible transmittance of the transparent panel 100 is greater than 70%.

The substrate 110 is a transparent substrate, such as a glass substrate, a polymer substrate or other suitable substrates. The material of the polymer substrate includes, for example, polyethylene terephthalate (PET), polycarbonate (PC), polyethylene naphthalate (PEN) or other suitable transparent polymer materials. In an exemplary example, the substrate is a glass substrate.

The touch sensing module 120 may be a capacitive touch sensing module, which locates the touch position through the capacitance change caused by the touch, but the disclosure is not limited thereto. In other embodiments, the touch sensing module 120 may be a resistive touch sensing module, which locates the touch position through the resistance change caused by the touch.

The touch sensing module 120 is schematically shown in FIG. 1 for convenience of description, but is not intended to limit the disclosure. The touch sensing module 120 may include a sensing layer, a protective layer, a gap layer or other components according to actual needs, and the disclosure is not limited thereto.

Referring to FIGS. 1 and 2, the organic photovoltaic module 130 includes a first electrode 131, a hole transporting layer 132, an active layer 133, an electron transporting layer 134, an exciton blocking layer 135, and a second electrode 136, so as to absorb light energy through the active layer 133 to form electron-hole pairs, and transmit holes and electrons to the first electrode 131 and the second electrode 136 through the hole transporting layer 132 and the electron transporting layer 134, respectively, to generate electrical energy, so that the transparent panel 100 is rechargeable.

The first electrode 131 is disposed on the second surface 110b of the substrate 110 and is in direct contact with the second surface 110b. The material of the first electrode 131 is transparent conductive oxide (TCO), such as indium tin oxide (ITO), gallium doped zinc oxide (GZO), aluminum doped zinc oxide (AZO), indium zinc oxide (IZO), zinc boron oxide (BZO), tin oxide or other suitable transparent conductive materials. In some embodiments, the first electrode 131 is the anode of the organic photovoltaic module 130.

The hole transporting layer 132 is disposed on the first electrode 131. The material of the hole transporting layer 132 may be metal oxide, such as molybdenum trioxide (MoO3), vanadium pentoxide (V2O5), nickel oxide (NiOx) or other suitable materials.

The active layer 133 is disposed on the hole transporting layer 132 and includes an acceptor material and a donor material. The donor material is selected from the group consisting of Boron subphthalocyanine chloride (SubPc), Copper(II) phthalocyanine (CuPc), Poly[[4,8-bis [5-(2-ethylhexyl)-2-thienyl]benzo[1,2-b:4,5-bldithiophene-2,6-diyl][2-(2-ethyl-1-oxohexyl)thieno[3,4-h]thiophenediyl]](PBDTTT-CT), N,N′-B is [4-(diphenylamino)phenyl]-N,N′-di(1-naphthyl)benzidine (NPB-DPA), chloroaluminum phthalocyanine (ClAlPc), phthalocyanine platinum (PtPc) or other suitable electron donating materials. The acceptor material is selected from the group consisting of carbon 60 (C60), carbon 70 (C70), phenyl C60-butyric acid methyl ester (PC60BM), phenyl C61-butyric acid methyl ester (PC61BM), phenyl C70-butyric acid methyl ester (PC70BM), phenyl C71-butyric acid methyl ester (PC71BM) or other suitable electron accepting materials.

In some embodiments, the active layer 133 may absorb light outside the visible light band (e.g., ultraviolet light), and allow visible light to penetrate, so that the organic photovoltaic module 130 may have good transparency for visible light, and at the same time, have good power conversion efficiency by absorbing light outside the visible light band.

The electron transporting layer 134 is disposed on the active layer 133. The material of the electron transporting layer 134 may be carbon 60 (C60), carbon 70 (C70), titanium oxide (TiOx), zinc oxide (ZnO), tin dioxide (SnO2) or other suitable materials.

The exciton blocking layer 135 is disposed on the electron transporting layer 134 to prevent electrons from combining with holes. The exciton blocking layer 135 may be selected from the group consisting of free bathocuproine (BCP), 2-(4-biphenylyl)-5-(4-t-butylphenyl)-1,3,4-oxadiazole (PBD), Bathophenanthroline (Bphen), 4-(Naphthalen-1-yl)-3,5-diphenyl-4H-1,2,4-triazole (NTAZ), and 2,2′-(4,4′-(Phenylphosphoryl)bis(4,1-phenylene))bis(1-phenyl-1H-benzo[d]imidazole) (BIPO).

The second electrode 136 is disposed on the exciton blocking layer 135. The material of the second electrode 136 is metal, metal oxide or metal alloy with high transmittance, such as aluminum, silver, copper, zinc or oxide or alloy formed by the above metal. In some embodiments, the second electrode 136 is the cathode of the organic photovoltaic module 130.

The organic photovoltaic module 130 is schematically shown in FIG. 2 for convenience of description, but is not intended to limit the disclosure. The organic photovoltaic module 130 may include other components according to actual needs, and the disclosure is not limited thereto.

Because the transparent panel 100 of the embodiment may form the touch sensing module 120 and the organic photovoltaic module 130 on both sides of the substrate 110 (i.e., the first surface 110a and the second surface 110b), respectively, and the transparent panel 100 having touch and photoelectric conversion functions may be obtained without combining the two substrates, the overall thickness of the transparent panel 100 may be reduced. In addition, the active layer 133 of the organic photovoltaic module 130 in the embodiment adopts organic materials and has high transmittance to visible light, and combined with high-penetration electrodes, the average visible transmittance of the transparent panel 100 is greater than 70%, and the color rendering index is greater than 90%. Thus, the transparent panel 100 is adapted for application in a display device.

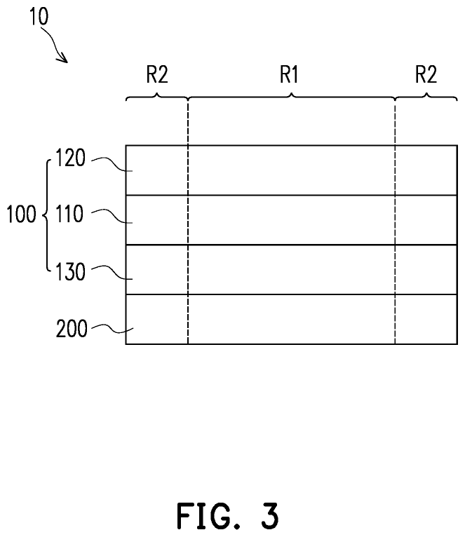

FIG. 3 is a schematic cross-sectional view of a display device according to an embodiment of the disclosure. It should be noted here that the embodiment of FIG. 2 uses the element numbers and a part of the content of the embodiment of FIG. 1, and the same or similar numbers are used to represent the same or similar elements, and the description of the same technical content is omitted. For the description of the omitted part, reference may be made to the foregoing embodiment, and details are not described herein. In addition, FIG. 3 merely schematically illustrates the relative relationship of the positions of the various layers in the structure, and thicknesses of the various layers and the relative relationship between the thicknesses may be adjusted according to actual needs, which is not limited in the disclosure.

Referring to FIG. 3, a display device 10 includes the transparent panel 100 and a display 200. The transparent panel 100 may be the transparent panel 100 of FIG. 1, which includes the substrate 110, the touch sensing module 120, and the organic photovoltaic module 130. The substrate 110 has the first surface 110a and the second surface 110b opposite to the first surface 110a. The touch sensing module 120 is disposed on the first surface 110a of the substrate 110. The organic photovoltaic module 130 is disposed on the second surface 110b of the substrate 110. The average visible transmittance of the transparent panel 100 is greater than 70%. The display 200 is disposed on a surface of the organic photovoltaic module 130 away from the substrate 110. In the embodiment, light enters from an outer surface of the touch sensing module 120, passes through the substrate 110, and then enters the organic photovoltaic module 130.

The display device 10 includes a display area R1 and a non-display area R2. For example, the non-display area R2 is at least on a side of the display area R1. In some embodiments, the non-display area R2 surrounds the display area R1, but the disclosure is not limited thereto.

The organic photovoltaic module 130 overlaps the display area R1 in a normal direction of the substrate 110. Since the organic photovoltaic module 130 has good transparency for visible light, the organic photovoltaic module 130 may cover the display area R1 without affecting the display effect of the display device 10, and may increase the light receiving area of the organic photovoltaic module 130 to increase the power generation capacity of the organic photovoltaic module 130.

In some embodiments, the organic photovoltaic module 130 overlaps the display area R1 and the non-display area R2 in the normal direction of the substrate 110, so as to further increase the light receiving area of the organic photovoltaic module 130.

In some embodiments, the display 200 may be a liquid crystal display, a micro light emitting diode display, an organic light emitting diode display or other suitable displays, but the disclosure is not limited thereto.

In some embodiments, an adhesive layer (not shown) may be included between the display 200 and the transparent panel 100 to bond the display 200 and the transparent panel 100.

In some embodiments, cover glass may be disposed on a surface of the transparent panel 100 away from the display 200 to protect the transparent panel and reduce the possibility of being scratched and stained.

To sum up, the transparent panel of the disclosure may integrate the touch sensing module and the organic photovoltaic module on the same substrate, and the transparent panel with touch and photoelectric conversion functions may be obtained without combining the two substrates. Thus, the overall thickness of the transparent panel may be reduced. In addition, the active layer of the organic photovoltaic module of the disclosure adopts organic materials and has high transmittance to visible light, and combined with high-penetration electrodes, the average visible transmittance of the transparent panel is greater than 70%, and the color rendering index is greater than 90%. Thus, the transparent panel is adapted for application in a display device to provide touch and photoelectric conversion functions for the display device.

Although the disclosure has been described with reference to the above embodiments, the described embodiments are not intended to limit the disclosure. People of ordinary skill in the art may make some changes and modifications without departing from the spirit and the scope of the disclosure. Thus, the scope of the disclosure shall be subject to those defined by the attached claims.

What is claimed is:

1. A transparent panel, comprising:
a substrate, having a first surface and a second surface opposite to the first surface;
a touch sensing module, disposed on the first surface of the substrate; and
an organic photovoltaic module, disposed on the second surface of the substrate, wherein an average visible transmittance of the transparent panel is greater than 70%.

2. The transparent panel according to claim 1, wherein the organic photovoltaic module comprises:
a first electrode, disposed on the second surface of the substrate;
a hole transporting layer, disposed on the first electrode;
an active layer, disposed on the hole transporting layer;
an electron transporting layer, disposed on the active layer;
an exciton blocking layer, disposed on the electron transporting layer; and
a second electrode, disposed on the exciton blocking layer.

3. The transparent panel according to claim 2, wherein the active layer comprises a receptor material and a donor material.

4. The transparent panel according to claim 3, wherein the donor material is selected from a group consisting of SubPc, CuPc, PBDTTT-C-T, NPB-DPA, ClA1Pc, and PtPc.

5. The transparent panel according to claim 3, wherein the acceptor material is selected from a group consisting of carbon 60, carbon 70, PC60BM, PC61BM, PC70BM, and PC71BM.

6. The transparent panel according to claim 2, wherein a material of the first electrode comprises transparent conductive oxide, and a material of the second electrode comprises metal, metal oxide or metal alloy.

7. A display device, comprising:
a transparent panel, comprising:
a substrate, having a first surface and a second surface opposite to the first surface;
a touch sensing module, disposed on the first surface of the substrate; and
an organic photovoltaic module, disposed on the second surface of the substrate, wherein an average visible transmittance of the transparent panel is greater than 70%; and
a display, disposed on a surface of the organic photovoltaic module away from the substrate.

8. The display device according to claim 7, wherein the display device comprises a display area and a non-display area, and the organic photovoltaic module overlaps the display area in a normal direction of the substrate.
